(19) United States
(12) Patent Application Publication
(10) Pub. No.: US 2026/0293323 A1
(43) Pub. Date: Sep. 24, 2026

(54) METHOD OF FORMING STRUCTURES FOR THRESHOLD VOLTAGE CONTROL

(71) Applicant: ASM IP Holding B.V., Almere (NL)

(72) Inventors: Oreste Madia, Leuven (BE); Giuseppe Alessio Verni, Jodoigne (BE); Qi Xie, Wilsele (BE); Michael Eugene Givens, Oud-Heverlee (BE); Varun Sharma, Helsinki (FI); Andrea Illiberi, Leuven (BE)

(21) Appl. No.: 19/693,782

(22) Filed: Jun. 1, 2026

Related U.S. Application Data
(63) Continuation of application No. 17/499,970, filed on Oct. 13, 2021, now Pat. No. 12,672,357.
(60) Provisional application No. 63/092,790, filed on Oct. 16, 2020.

(51) Int. Cl. H10D 99/00; H10P 14/60

(52) U.S. Cl. CPC H10D 99/00; H10P 14/6339

(57) ABSTRACT

Methods and systems for depositing threshold voltage shifting layers onto a surface of a substrate and structures and devices formed using the methods are disclosed. An exemplary method includes using a cyclical deposition process, depositing a threshold voltage shifting layer onto a surface of the substrate. The threshold voltage shifting layers are particularly useful for metal oxide semiconductor field effect transistors.

### CROSS-REFERENCE TO RELATED APPLICATIONS

This application is a continuation of, and claims priority to, U.S. patent application Ser. No. 17/499,970 filed Oct. 13, 2021 titled METHOD OF FORMING STRUCTURES FOR THRESHOLD VOLTAGE CONTROL; which is a continuation of and claims priority to U.S. Patent Application Ser. No. 63/092,790, filed on Oct. 16, 2020, titled METHOD OF FORMING STRUCTURES FOR THRESHOLD VOLTAGE CONTROL, the disclosures of which are hereby incorporated by reference in their entirety.

### FIELD OF INVENTION

This application is a continuation of, and claims priority to, U.S. patent application Ser. No. 17/499,970 filed Oct. 13, 2021 titled METHOD OF FORMING STRUCTURES FOR THRESHOLD VOLTAGE CONTROL; which is a continuation of and claims priority to U.S. Patent Application Ser. No. 63/092,790, filed on Oct. 16, 2020, titled METHOD OF FORMING STRUCTURES FOR THRESHOLD VOLTAGE CONTROL, the disclosures of which are hereby incorporated by reference in their entirety.

The present disclosure generally relates to methods and systems suitable for forming a layer on a surface of a substrate and to structures including the layer. More particularly, the disclosure relates to methods and systems for forming layers that allow controlling the threshold voltage of metal-oxide-semiconductor field-effect transistors (MOSFETs) and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes. For example, one challenge has been finding a suitable dielectric stacks that form an insulating barrier between a gate and a channel of a field effect transistor. One particular problem in this regard is controlling the threshold voltage of field effect transistors.

The following prior art is made of record: JP3589954 describes an electromagnetic wave detector and image detector. U.S. Pat. No. 9,773,818 describes a display device having transparent conductive film and metal film. US20200052056 describes an organic light emitting diode display device and method of manufacturing an organic light emitting diode display device. U.S. Pat. No. 8,823,672 describes a touch panel display device. WO2017171739 describes transistor gate-channel arrangements. WO2006055226 describes a nitrogen-containing field effect transistor gate stack containing a threshold voltage control layer formed via deposition of a metal oxide. US2012161126 describes a semiconductor device and a manufacturing method thereof. U.S. Pat. No. 9,780,225 describes a semiconductor device and a manufacturing method thereof.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming structures including threshold voltage shifting layers, to structures and devices formed using such methods, and to apparatus for performing the methods and/or for forming the structures and/or devices. The threshold voltage shifting layers can be used in a variety of applications, including work function adjustment layers. Additionally or alternatively, they can be used as threshold voltage adjustment layers, or as p-type dipole shifting layers.

The cyclical deposition process can include one or more of an atomic layer deposition process and a cyclical chemical vapor deposition process. The cyclical deposition process can include a thermal process—i.e., a process that does not use plasma-activated species. In some cases, an oxygen reactant can be exposed to a plasma to form activated oxygen reactant species, e.g. radicals and/or ions.

In one aspect, described herein is a method for depositing a layer for controlling a threshold voltage of a metal-oxide-semiconductor field effect transistor (MOSFET), the method comprising the steps of: providing a substrate within a reactor chamber, the substrate comprising a surface, the surface comprising a silicon oxide surface and/or a high k dielectric surface; using a cyclical deposition process, depositing a threshold voltage shifting layer onto the silicon oxide surface and/or on the high k dielectric surface; wherein the threshold voltage shifting layer comprises gallium and oxygen; wherein the cyclical deposition process comprises: providing a gallium precursor to the reaction chamber; and providing an oxygen reactant to the reaction chamber.

In some embodiments, the oxygen reactant is selected from the list consisting of O₂, O₃, H₂O, H₂O₂, and N₂O.

In some embodiments, the gallium precursor is selected from the list: gallium beta diketonates, gallium alkoxides, gallium alkyls, gallium alkylamides, gallium halides, and gallanes.

In some embodiments, the gallium precursor is selected from the list consisting of Gallium tris(dimethylamide), Gallium(III) acetylacetonate, dimethylgallium isopropoxide, gallium chloride, and trimethylgallium.

In some embodiments, the cyclic deposition process comprises a sequence of a water pulse, a gallium precursor pulse, and an ozone pulse.

In some embodiments, the cyclic deposition process comprises a sequence of a water pulse, a gallium precursor pulse, and an oxygen pulse.

In some embodiments, the cyclic deposition process comprises a sequence of an ozone pulse, a gallium precursor pulse, and a water pulse.

In some embodiments, the cyclic deposition process comprises a sequence of an oxygen pulse, a gallium precursor pulse, and a water pulse.

In some embodiments, the cyclic deposition process comprises a sequence of an ozone pulse, a gallium precursor pulse, and an oxygen pulse.

In some embodiments, the cyclic deposition process comprises a sequence of an oxygen pulse, a gallium precursor pulse, and an ozone pulse.

In some embodiments, the threshold voltage shifting layer further comprises indium, and wherein the cyclic deposition process further comprises a step of providing an indium precursor to the reaction chamber.

In some embodiments, the cyclic deposition process comprises a plurality of pulses, the plurality of pulses comprises one or more gallium precursor pulses, one or more indium precursor pulses, and one or more oxygen reactant pulses; wherein the gallium precursor is provided to the reaction chamber in the one or more gallium precursor pulses, wherein the indium precursor is provided to the reaction chamber in the indium precursor pulse, wherein the oxygen reactant is provided to the reaction chamber in oxygen reactant pulses; and wherein the pulses are provided in any one of the following sequences: gallium precursor pulse, indium precursor pulse, oxygen reactant pulse; or, indium precursor pulse, gallium precursor pulse, oxygen reactant pulse.

In some embodiments, the indium precursor is selected from indium alkyls, indium halides, indium beta diketonates, indium alkoxides, and indium alkylamides.

In some embodiments, the indium precursor is selected from the list trimethyl indium, tri(dimethylamino) indium, triethyl indiumTEIn, cyclopentadienyl Indium, InCl₃, 3-(dimethylamino)propyl]dimethyl-indium, indium hexafluoroacetylacetone, Indium acetylacetonate.

In some embodiments, the threshold voltage shifting layer further comprises zinc, and wherein the cyclic deposition process further comprises a step of providing a zinc precursor to the reaction chamber.

In some embodiments, the zinc precursor is selected from zinc alkyls, zinc halides, zinc beta diketonates, zinc alkoxides, and zinc alkylamides.

In some embodiments, the threshold voltage shifting layer further comprises tin, and wherein the cyclic deposition process further comprises a step of providing a tin precursor to the reaction chamber.

In some embodiments, the tin precursor is selected from tin alkyls, tin halides, tin beta diketonates, tin alkoxides, and tin alkylamides.

Further described herein is a method for depositing a layer for controlling a threshold voltage of a metal-oxide-semiconductor field effect transistor (MOSFET), the method comprising the steps of: providing a substrate within a reactor chamber, the substrate comprising a surface, the surface comprising a silicon oxide surface and/or a high k dielectric surface; using a cyclical deposition process, depositing a threshold voltage shifting layer onto the silicon oxide surface and/or on the high k dielectric surface; wherein the threshold voltage shifting layer comprises tin and oxygen; wherein the cyclical deposition process comprises: providing a tin precursor to the reaction chamber; and providing an oxygen reactant to the reaction chamber.

In some embodiments, the oxygen reactant is selected from the list consisting of O₂, O₃, H₂O, H₂O₂, and N₂O.

In some embodiments, the tin precursor is selected from the list: tin beta diketonates, tin alkoxides, tin alkyls, tin alkylamides, tin halides, organostannanes, and stannanes.

In some embodiments, the cyclic deposition process comprises a sequence of a water pulse, a tin precursor pulse, and an ozone pulse.

In some embodiments, the cyclic deposition process comprises a sequence of a water pulse, a tin precursor pulse, and an oxygen pulse.

In some embodiments, the cyclic deposition process comprises a sequence of an ozone pulse, a tin precursor pulse, and a water pulse.

In some embodiments, the cyclic deposition process comprises a sequence of an oxygen pulse, a tin precursor pulse, and a water pulse.

In some embodiments, the cyclic deposition process comprises a sequence of an ozone pulse, a tin precursor pulse, and an oxygen pulse.

In some embodiments, the cyclic deposition process comprises a sequence of an oxygen pulse, a tin precursor pulse, and an ozone pulse.

Further described is a method for depositing a layer for controlling a threshold voltage of a metal-oxide-semiconductor field effect transistor (MOSFET), the method comprising the steps of: providing a substrate within a reactor chamber, the substrate comprising a surface, the surface comprising a silicon oxide surface and/or a high k dielectric surface; using a cyclical deposition process, depositing a threshold voltage shifting layer onto the silicon oxide surface and/or on the high k dielectric surface; wherein the threshold voltage shifting layer comprises zinc and oxygen; and, wherein the cyclical deposition process comprises: providing a zinc precursor to the reaction chamber; and providing an oxygen reactant to the reaction chamber.

In some embodiments, the oxygen reactant is selected from the list consisting of O₂, O₃, H₂O, H₂O₂, and N₂O.

In some embodiments, the zinc precursor is selected from the list: zinc beta diketonates, zinc alkoxides, zinc alkyls, zinc alkylamides, zinc halides, and zinc hydrides.

In some embodiments, the cyclic deposition process comprises a sequence of a water pulse, a zinc precursor pulse, and an ozone pulse.

In some embodiments, the cyclic deposition process comprises a sequence of a water pulse, a zinc precursor pulse, and an oxygen pulse.

In some embodiments, the cyclic deposition process comprises a sequence of an ozone pulse, a zinc precursor pulse, and a water pulse.

In some embodiments, the cyclic deposition process comprises a sequence of an oxygen pulse, a zinc precursor pulse, and a water pulse.

In some embodiments, the cyclic deposition process comprises a sequence of an ozone pulse, a zinc precursor pulse, and an oxygen pulse.

In some embodiments, the cyclic deposition process comprises a sequence of an oxygen pulse, a zinc precursor pulse, and an ozone pulse.

In some embodiments, the cyclic deposition process comprises a step of contacting the substrate with a surface modification agent, the surface modification agent comprising an alcohol or an acid anhydride.

In some embodiments, the surface modification agent comprises an alcohol selected from methanol, ethanol, and isopropanol.

In some embodiments, the surface modification agent comprises an acid anhydride selected from formic anhydride and acetic anhydride.

In some embodiments, the threshold voltage shifting layer has a thickness from at least 0.03 nm to at most 1.0 nm.

In some embodiments, the threshold voltage shifting layer is deposited at a temperature of at least 80° C. to at most 300° C.

In some embodiments, the threshold voltage shifting layer is deposited at a pressure of at least 1.0 Torr to at most 10.0 Torr.

In some embodiments, the cyclical deposition process comprises a cyclical chemical vapor deposition process.

In some embodiments, the cyclical deposition process comprises a thermal process.

Further described herein is a structure comprising a threshold voltage shifting layer formed according to a method as described herein.

In some embodiments, the structure comprises a high-k dielectric layer between the threshold voltage shifting layer and a substrate.

In some embodiments, the threshold voltage shifting layer is positioned between a high-k dielectric layer and a substrate.

In some embodiments, a thickness of the threshold voltage shifting layer is from at least 0.03 nm to at most 1.0 nm.

Further described is a gate all around metal oxide semiconductor field effect transistor comprising a structure as described herein.

Further described is a system comprising one or more reaction chambers; a precursor gas source comprising a gallium precursor; an oxygen reactant gas source comprising an oxygen reactant; an exhaust source; and a controller, wherein the controller is configured to control gas flow into at least one of the one or more reaction chambers to form a layer for controlling a threshold voltage of a MOSFET according to a method as described herein.

In accordance with yet further exemplary embodiments of the disclosure, a structure is formed using a method as described herein. The structure can include a substrate and a threshold voltage shifting layer formed overlying a surface of the substrate. Exemplary structures can further include one or more additional layers, such as an additional metal or conducting layer overlying the threshold voltage shifting layers and/or one or more insulating or dielectric layers underneath the threshold voltage shifting layers. The structure can be or form part of a CMOS structure, such as one or more of a PMOS and NMOS structure, or other device structure.

In accordance with yet additional embodiments of the disclosure, a device or portion thereof can be formed using a method and/or a structure as described herein. The device can include a substrate, an insulating or dielectric layer, a threshold voltage shifting layer overlying the insulating or dielectric layer, and optionally an additional metal layer overlying the threshold voltage shifting layer. The device can be or form part of, for example, a CMOS device.

In accordance with yet additional embodiments of the disclosure, a device or portion thereof can be formed using a method and/or a structure as described herein. The device can include a substrate, an interfacial layer such as a silicon oxide layer, a threshold voltage shifting layer overlying the interfacial layer, a high-k dielectric layer overlying the threshold voltage shifting layer, and optionally an additional metal layer overlying the threshold voltage shifting layer. The device can be or form part of, for example, a CMOS device.

In accordance with yet additional examples of the disclosure, a system to perform a method as described herein and/or to form a structure, device, or portion of either, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2-4 illustrate exemplary structures in accordance with embodiments of the disclosure.

FIG. 5 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures, such as gate dielectrics or portions thereof for field effect transistors. Exemplary methods can be used to, for example, form CMOS devices, or portions of such devices. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas or inert gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “oxygen reactant” can be used to denote a reactant comprising oxygen. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material. In some embodiments the substrate surface can include several materials simultaneously.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

As used herein, the term “gate all around transistor” may refer to devices which include a gate stack comprising a gate dielectric and a conductive material wrapped around a semiconductor channel region. As used herein, the term “gate all around transistor” may also refer to a variety of device architectures such as nanosheet devices, forksheet devices, vertical field effect transistors, stacked device architectures, etc.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes are not necessarily comprised of a sequence of self-limiting surface reactions.

As used herein, a “gallium precursor” includes a gas or a material that can become gaseous and that can be represented by a chemical formula that includes gallium.

As used herein, an “indium precursor” includes a gas or a material that can become gaseous and that can be represented by a chemical formula that includes indium.

As used herein, a “tin precursor” includes a gas or a material that can become gaseous and that can be represented by a chemical formula that includes tin.

As used herein, a “zinc precursor” includes a gas or a material that can become gaseous and that can be represented by a chemical formula that includes zinc.

As used herein, the term “reactant” includes a gas or a material that can become gaseous and that can, together with one or more of the precursors mentioned herein, be used to form a layer on a substrate. Particularly employed herein are oxygen-containing reactants, also known as oxygen reactants. The term “oxygen reactant” can refer to a gas or a material that can become gaseous and that can be represented by a chemical formula that includes oxygen. In some cases, the chemical formula includes oxygen and hydrogen. In some cases, the oxygen reactant does not include diatomic oxygen. Exemplary oxygen reactants include H₂O₂, H₂O, O₂, O₃, and N₂O.

The term “threshold voltage” as used herein refers to a minimum gate voltage required to create a conductive path between the source and drain terminals of a field effect transistor.

The term “threshold voltage shifting layer”, refers to a layer which can be used in the gate stack of a field effect transistor, and which can change the threshold voltage of that field effect transistor. When used herein, the term “threshold voltage shifting layer” may be equivalent to like terms such as threshold voltage adjusting layer, work function adjusting layer, work function shifting layer, tunable threshold voltage layer, flatband voltage adjusting layer, flatband voltage shifting layer, or simply “layer”.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The presently described methods and devices are useful for controlling the threshold voltage of field effect transistors. In particular, the present methods and devices are particularly useful for controlling the threshold voltage of n-channel or p-channel field effect transistors, such as n-channel-or p-channel metal-oxide semiconductor field effect transistors, such as n-channel or p-channel gate-all-around metal oxide semiconductor field effect transistors. In particular, the present methods and devices are particularly useful for inducing a positive flatband voltage shift for p-channel metal oxide semiconductor field effect transistors (p-MOSFETs). Also, the present methods and devices are particularly useful for inducing a negative flatband voltage shift for n-channel metal oxide semiconductor field effect transistors (n-MOSFETS). Thus, the present methods and devices are particularly useful for increasing the gate voltage at which a conductive channel is produced between the source and drain of a p-MOSFET. Also, the present methods and devices are particularly useful for decreasing the gate voltage at which a conductive channel is produced between the source and drain of an n-MOSFET. The n-MOSFETs and/or p-MOSFETs may, for example, be comprised in a CMOS-based integrated circuit. In other words, the present methods and devices are particularly useful for increasing the voltage at which a p-MOSFET switches from an off-state to an on-state, and they are useful for decreasing the voltage at which an n-MOSFET switches from an off-state to an on-state. The present methods and devices are particularly useful for the manufacture of n-or p-MOSFETS with a gate-all-around architecture, or similar architectures. Additionally or alternatively, the present methods and devices may be of particular use in the context of systems-on-a-chip. Advantageously, the presently disclosed methods allow depositing threshold shifting layers contributing only minimally to the equivalent oxide thickness of the gate dielectric stack while simultaneously offering a low growth rate and providing a significant positive threshold voltage shift. Advantageously, the presently disclosed methods allow depositing threshold shifting layers having a low impurity content.

Thus described herein is a method for depositing a layer. The method comprises the provision of a substrate within a reactor chamber. The substrate comprises a surface which in its turn comprises a silicon oxide surface and/or a high k dielectric surface. A threshold voltage shifting layer is then deposited onto the silicon oxide surface and/or on the high k dielectric surface. Advantageously, the threshold voltage shifting layer may be deposited by means of a cyclical deposition process.

In some embodiments, the cyclic deposition process comprises a plurality of precursor pulses and a plurality of oxygen reactant pulses. It shall be understood that the precursor pulses and the oxygen reactant pulses may be provided alternatingly. During the precursor pulses, one or more of a gallium precursor, an indium precursor, a zinc precursor, and a tin precursor are provided to the reaction chamber. During the oxygen reactant pulses, an oxygen reactant is provided to the reaction chamber.

In some embodiments, the threshold voltage shifting layer comprises gallium and oxygen. In other words, the threshold voltage shifting layer comprises gallium oxide in these embodiments. Also, in these embodiments, the cyclical deposition process comprises providing a gallium precursor to the reaction chamber and providing an oxygen reactant to the reaction chamber.

In a specific embodiment, gallium oxide is deposited by means of a cyclical deposition process comprising one or more cycles, the cycles comprising an oxygen reactant pulse, an oxygen reactant purge, a gallium precursor pulse, and a precursor purge. A suitable oxygen reactant includes ozone. A suitable gallium precursor includes Tris(dimethylamido)gallium(III) (TDMAGa). The cyclical deposition process may occur at a temperature of at least 150° C. to at most 250° C., e.g. at a temperature of about 200° C. The cyclical deposition process may occur at a pressure of, for example, at least 1.0 Torr base pressure to at most 8.0 Torr base pressure, e.g. at about 4.0 Torr base pressure. Suitably a continuous inert gas flow, e.g. an N₂ flow, such as an N₂ flow of e.g. 325 sccm, may be maintained through one or more precursor lines connected to the reaction chamber. Accordingly, the inert gas may suitably serve as a sweep gas. A precursor line may refer to tubing that carries one or more precursors or reactants from a precursor or reactant source to the reaction chamber. An oxygen reactant pulse may, for example, last from at least 0.1 s to at most 10.0 s, or about 2.0 s. An oxygen reactant purge may, for example, last from at least from at least 1.0 s to at most 6.0 s, for example about 3.0 s. A gallium precursor pulse may, for example, last from at least 0.5 s to at most 5.0 s, for example for about 1.5 s. A precursor purge may, for example, last from at least 1.0 s to at most 10.0 s, for example about 5.0 s. The cyclical deposition process preferably comprises an oxygen reactant pulse as its first step, which may have a different duration than subsequent oxygen reactant pulses. In exemplary embodiments, such a first oxygen reactant pulse lasts from at least 0.1 s to at most 10.0 s, or about 3.0 s. A first oxygen reactant purge following the first oxygen reactant pulse may last, for example, from at least 1.0 s to at most 6.0 s.

The oxygen reactant may comprise an oxygen containing compound, an oxygen radical, or elementary oxygen. Exemplary oxygen reactants include O₂, H₂O, O₃, H₂O₂, and N₂O. In some embodiments, the method employs a cyclic deposition sequence involving a plurality of alternating precursor pulses and oxygen reactant pulses, wherein the oxygen reactant may be varied from one pulse to the other. For example, in some pulses H₂O may be used as oxygen reactant, in other pulses O₂ may be used as the oxygen reactant and in yet other pulses O₃ may be used as the oxygen reactant. In some embodiments, the oxygen reactant is selected from the list consisting of oxygen, ozone, and water. In some embodiments, the resulting growth rate is less than 1.0 nm per cycle, or less than 0.5 nm per cycle, or less than 0.4 nm per cycle, or less than 0.3 nm per cycle, or less than 0.2 nm per cycle, or less than 0.1 nm per cycle.

Suitable gallium precursors may be selected from gallium beta diketonates (such as Gallium tris-acetylacetonate, and Tris(2,2,6,6-tetramethyl-3,5-heptanedionato)gallium(III)), gallium alkoxides, gallium alkyls (such as Trimethylgallium or Triethylgallium), gallium alkylamides (such as gallium tris(dimethylamide), i.e. TDMAGa), gallium halides, and gallanes. For example, the gallium precursor may comprise Gallium tris(dimethylamide), Gallium(III) acetylacetonate (Ga(acac)₃), gallium alkoxides such as dimethylgallium isopropoxide, gallium halides such as gallium chloride, gallium tribromide, and gallium tri-iodide, and/or gallium alkyls such as trimethylgallium (TMGa). In some embodiments, carboxylates of gallium can be used as precursors, for example, gallium triacetate or gallium tripropionate.

In some embodiments, the gallium precursor comprises gallium Tris(dimethylamido)gallium-dimer and the oxygen reactant comprises O₂, H₂O, O₃, and H₂O₂, and/or N₂O. In some embodiments, the precursor comprises gallium tris(dimethylamide) and the oxygen reactant comprises ozone.

In some embodiments, the cyclic deposition process comprises one to six, one to five, or one to four cycles of the following pulsing sequence, in the following order: water pulse, gallium precursor pulse, ozone pulse, gallium precursor pulse. The gallium precursor may comprise any precursor mentioned herein, such as Gallium tris(dimethylamide).

In some embodiments, a gallium carboxylate such as gallium triacetate is used as a gallium precursor, and the co-reactant is selected from the list consisting of H₂O, NH₃, O₂, O₃ and H₂O₂.

In some embodiments, the cyclic deposition process comprises one or more cycles of the following pulsing sequence, in any order: water pulse, gallium precursor pulse, ozone pulse, gallium precursor pulse.

In some embodiments, the method of forming a threshold voltage shifting layer comprise of one or more of the following pulsing sequence: gallium precursor pulse, first oxygen reactant pulse, gallium precursor pulse, second oxygen reactant pulse. Thus a gallium oxide threshold voltage shifting layer is formed on the substrate. Suitably, the substrate on which the threshold voltage shifting layer is deposited comprises an interfacial layer, e.g. silicon oxide, and the gallium oxide layer is deposited on the interfacial layer. Suitably, the gallium oxide threshold voltage shifting layer may be directly deposited on the interfacial layer. A high-k dielectric layer may thereafter be deposited on the gallium oxide threshold voltage shifting layer. Suitably, the method of forming a threshold voltage shifting layer consists of 1 to 16 cycles, 1 to 8 cycles, 1 to 4 cycles, or 1 to 2 cycles of the following pulsing sequence: gallium precursor pulse, first oxygen reactant pulse, gallium precursor pulse, second oxygen reactant pulse. The gallium precursor used for the gallium precursor pulse may comprise a gallium alkylamide such as Tris(dimethylamido)gallium(III). Note that Tris(dimethylamido)gallium(III) may be provided as a dimer. The first oxygen reactant pulse and/or the second oxygen reactant pulse may employ an oxygen-containing oxidant such as water, ozone, or oxygen. Suitably, the first oxygen reactant pulse may employ water. Suitably, the second oxygen reactant pulse may employ ozone.

The threshold voltage shifting layer may further comprise indium. Accordingly, and in some embodiments, the threshold voltage shifting layer further comprises indium. In such embodiments, the cyclic deposition process further comprises a step of providing an indium precursor to the reaction chamber. Accordingly, Indium Gallium Oxide-based threshold voltage shifting layers maybe deposited.

In some embodiments, the cyclic deposition process comprises a plurality of pulses. The plurality of pulses comprises one or more gallium precursor pulses, one or more indium precursor pulses, and one or more oxygen reactant pulses. The gallium precursor is provided to the reaction chamber in the one or more gallium precursor pulses, the indium precursor is provided to the reaction chamber in the indium precursor pulse, and the oxygen reactant is provided to the reaction chamber in oxygen reactant pulses. The aforementioned pulses may be provided in any one of the following sequences: gallium precursor pulse, indium precursor pulse, oxygen reactant pulse; or, indium precursor pulse, gallium precursor pulse, oxygen reactant pulse; or, indium precursor pulse, oxygen reactant pulse; gallium precursor pulse, oxygen reactant pulse; or, gallium precursor pulse, oxygen reactant pulse; indium precursor pulse, oxygen reactant pulse. In other words, the aforementioned pulses may be provided to the reaction chamber in any one of the given orders. Particularly advantageous threshold shifting layers may be obtained by sequentially providing a gallium precursor and an indium precursor to the reaction chamber in any order, and subsequently providing an oxygen reactant pulse to the reaction chamber. This sequence may be carried out once, or may be repeated for e.g. 2, 3, 4, 5, 6, or more times in order to form the threshold shifting layer. Without the invention being bound by theory or any particular mode of operation, it is believed that the improved properties are a result from a more uniform surface coverage which is enabled by interlacing of gallium and indium precursors of a different size, e.g. by interlacing of larger gallium precursors and smaller indium precursors.

In some embodiments, the indium precursor is selected from indium alkyls (such as Trimethyl Indium and Triethyl Indium), indium halides (such as Indium Chloride, dichloride, and trichloride), indium beta diketonates (such as Indium tris-acetylacetonate), indium alkoxides, and indium alkylamides. Exemplary indium precursors include trimethyl indium (TMIn), TDMAIn, triethyl indium (TEIn), Cyclopentadienyl Indium (Cp-In), InCl₃, 3-(dimethylamino)propyl]dimethyl-indium, Indium Hexafluoroacetylacetone (In(hfac)₃), Indium acetylacetonate (In(acac)₃).

In some embodiments, the indium precursor comprises trimethylindium and the gallium precursor comprises Gallium tris(dimethylamide).

In some embodiments, the indium precursors comprises an indium alkyl such as trimethylindium and the gallium precursor comprises a gallium carboxylate such as gallium triacetate. In such embodiments, the cyclic deposition process suitably comprises, in the following order, the following sequence of pulses: a gallium precursor pulse, an oxygen reactant pulse, an indium precursor pulse, and an oxygen reactant pulse. Additionally or alternatively, such a cyclic deposition process may comprise, in the following order, an oxygen reactant pulse, a gallium precursor pulse, an oxygen reactant pulse, and an indium precursor pulse. Additionally or alternatively, such a cyclic deposition process may comprise a gallium precursor pulse directly after an indium precursor pulse, or an indium precursor pulse directly after a gallium precursor pulse, then followed by an oxygen reactant pulse.

In a specific embodiment, InGaOx is deposited by means of a cyclical deposition process comprising one or more cycles, the cycles comprising an oxygen reactant pulse, an oxygen reactant purge, a gallium precursor pulse, an indium precursor pulse, and a precursor purge. A suitable oxygen reactant includes ozone. A suitable gallium precursor includes Tris(dimethylamido)gallium(III). A suitable indium precursor includes trimethylindium. The cyclical deposition process may occur at a temperature of at least 200° C. to at most 250° C., e.g. at a temperature of about 225° C. The cyclical deposition process may occur at a pressure of, for example, at least 1.0 Torr base pressure to at most 8.0 Torr base pressure, e.g. at about 4.0 Torr base pressure. Suitably a continuous inert gas flow, e.g. an N₂ flow, such as an N₂ flow of e.g. 325 sccm, may be maintained through one or more precursor lines connected to the reaction chamber. Accordingly, the inert gas may suitably serve as a sweep gas. A precursor line may refer to tubing that carries one or more precursors or reactants from a precursor or reactant source to the reaction chamber. An oxygen reactant pulse may, for example, last from at least 0.1 s to at most 10.0 s, or about 2.0 s. An oxygen reactant purge may, for example, last from at least 1.0 s to at most 6.0 s, for example about 3.0 s. A gallium precursor pulse may, for example, last from at least 0.5 s to at most 5.0 s, for example for about 1.5 s. An indium precursor pulse may, for example, last from at least 0.5 s to at most 5.0 s, for example about 2.0 s. A precursor purge may, for example, last from at least 1.0 s to at most 10.0 s, for example about 3.0 s. Preferably, the gallium precursor pulse and the indium precursor pulse directly follow each other, without intervening purge or oxygen reactant pulse. This can improve the quality of the deposited layers. Also, the cyclical deposition process preferably comprises an oxygen reactant pulse as its first step, which may have a different duration than subsequent oxygen reactant pulses. In exemplary embodiments, such a first oxygen reactant pulse lasts from at least 0.1 s to at most 10.0 s, or about 3.0 s. A first oxygen reactant purge following the first oxygen reactant pulse may last, for example, from at least 1.0 s to at most 6.0 s.

In some embodiments, the threshold voltage shifting layer further comprises zinc. In these embodiments, the cyclic deposition process further comprises a step of providing a zinc precursor to the reaction chamber. Thus, a GaZnOx layer or an InGaZnOx containing threshold voltage shifting layer may be formed. In some embodiments, the zinc precursor is selected from zinc alkyls, zinc halides, zinc beta diketonates, zinc alkoxides, and zinc alkylamides.

In some embodiments, the threshold voltage shifting layer comprises indium, zinc and oxygen. In other words, the threshold voltage shifting layer comprises indium zinc oxide in these embodiments. Also, in these embodiments, the cyclical deposition process comprises providing an indium precursor to the reaction chamber, providing a zinc precursor to the reaction chamber, and providing an oxygen reactant to the reaction chamber. Advantageously, such layers may be deposited in a cyclical deposition process comprising an alternating sequence of precursor pulses and reactant pulses. The precursor pulses then comprise the provision of a zinc precursor and an indium precursor to the reaction chamber. The reactant pulses then comprise the provision of a reactant to the reaction chamber. Optionally, the precursor pulses and the reactant pulses are separated by purges.

In some embodiments, the threshold voltage shifting layers comprising indium, zinc, and oxygen are deposited using a cyclical deposition process comprising, in the following order, an indium precursor pulse, an oxygen precursor pulse, a zinc precursor pulse, and an oxygen precursor pulse.

In some embodiments, the threshold voltage shifting layers comprising indium, zinc, and oxygen are deposited using a cyclical deposition process comprising, in the following order, a zinc precursor pulse, an oxygen precursor pulse, an indium precursor pulse, and an oxygen precursor pulse.

In some embodiments, the threshold voltage shifting layer further comprises tin. Thus, indium gallium tin zinc oxide, indium gallium tin oxide, or gallium tin oxide threshold voltage shifting layers may be deposited. In these embodiments, the cyclic deposition process further comprises a step of providing a tin precursor to the reaction chamber. In some embodiments, the tin precursor is selected from tin alkyls, tin halides, tin beta diketonates, tin alkoxides, and tin alkylamides. Exemplary tin precursors include tin alkylamides such as tetrakis(dimethylamido)tin (TDMASn), and tin alkylamines such as N,N-tert-butyl-1,1-dimethylethylenediamine stannylene(II).

In some embodiments, the present methods are employed for growing an indium gallium zinc oxide threshold voltage shifting layer, and the indium precursor comprises trimethyl indium, the zinc precursor comprises diethyl zinc, and the gallium precursor comprises gallium tris(dimethylamide).

In some embodiments, the cyclic deposition process comprises a sequence, in the given order, of a water pulse, a gallium precursor pulse, and an ozone pulse. In some embodiments, the cyclic deposition process further comprises a tin precursor pulse, a zinc precursor pulse, and/or an indium precursor pulse between the water pulse and the ozone pulse.

In some embodiments, the cyclic deposition process comprises a sequence, in the given order, of a water pulse, a gallium precursor pulse, and an oxygen pulse. In some embodiments, the cyclic deposition process further comprises a tin precursor pulse, a zinc precursor pulse, and/or an indium precursor pulse between the water pulse and the oxygen pulse.

In some embodiments, the cyclic deposition process comprises a sequence, in the given order, of an ozone pulse, a gallium precursor pulse, and a water pulse. In some embodiments, the cyclic deposition process further comprises a tin precursor pulse, a zinc precursor pulse, and/or an indium precursor pulse between the ozone pulse and the water pulse.

In some embodiments, the cyclic deposition process comprises a sequence, in the given order, of an oxygen pulse, a gallium precursor pulse, and a water pulse. In some embodiments, the cyclic deposition process further comprises a tin precursor pulse, a zinc precursor pulse, and/or an indium precursor pulse between oxygen pulse and the water pulse.

In some embodiments, the cyclic deposition process comprises a sequence, in the given order, of an ozone pulse, a gallium precursor pulse, and an oxygen pulse. In some embodiments, the cyclic deposition process further comprises a tin precursor pulse, a zinc precursor pulse, and/or an indium precursor pulse between the ozone pulse and the oxygen pulse.

In some embodiments, the cyclic deposition process comprises a sequence, in the given order, of an oxygen pulse, a gallium precursor pulse, and an ozone pulse. In some embodiments, the cyclic deposition process further comprises a tin precursor pulse, a zinc precursor pulse, and/or an indium precursor pulse between the oxygen pulse and the ozone pulse.

Another material that may be used as a threshold voltage shifting layer is tin oxide. Accordingly, further described is another method for depositing a layer for controlling a threshold voltage of a metal-oxide-semiconductor field effect transistor (MOSFET). The method comprises a step of providing a substrate within a reactor chamber. The substrate comprises a surface. The surface comprises a silicon oxide surface and/or a high k dielectric surface. Using a cyclical deposition process, a threshold voltage shifting layer is deposited onto the silicon oxide surface and/or on the high k dielectric surface. The threshold voltage shifting layer comprises tin and oxygen. The cyclical deposition process comprises providing a tin precursor to the reaction chamber; and providing an oxygen reactant to the reaction chamber.

In some embodiments, the oxygen reactant is selected from the list consisting of O₂, O₃, and H₂O.

In some embodiments, the tin precursor is selected from the list: tin beta diketonates, tin alkoxides, tin alkyls, tin alkylamides, tin halides, organostannanes, and stannanes.

In some embodiments, the cyclic deposition process comprises a sequence of a water pulse, a tin precursor pulse, and an ozone pulse. In some embodiments, the cyclic deposition process comprises a sequence of a water pulse, a tin precursor pulse, and an oxygen pulse. In some embodiments, the cyclic deposition process comprises a sequence of an ozone pulse, a tin precursor pulse, and a water pulse. In some embodiments, the cyclic deposition process comprises a sequence of an oxygen pulse, a tin precursor pulse, and a water pulse. In some embodiments, the cyclic deposition process comprises a sequence of an ozone pulse, a tin precursor pulse, and an oxygen pulse. In some embodiments, the cyclic deposition process comprises a sequence of an oxygen pulse, a tin precursor pulse, and an ozone pulse.

In some embodiments, the threshold voltage shifting layer comprises indium, tin, and oxygen. In other words, the threshold voltage shifting layer comprises indium tin oxide in these embodiments. Also, in these embodiments, the cyclical deposition process comprises providing an indium precursor to the reaction chamber, providing a tin precursor to the reaction chamber, and providing an oxygen reactant to the reaction chamber. Advantageously, such layers may be deposited in a cyclical deposition process comprising an alternating sequence of precursor pulses and reagent pulses. The precursor pulses then comprise the provision of a tin precursor and an indium precursor to the reaction chamber. The reagent pulses then comprise the provision of a reagent to the reaction chamber. Optionally, the precursor pulses and the reagent pulses are separated by purges.

Another material that may be suitably used as a threshold voltage shifting layer is zinc oxide. Accordingly, further described is another method for depositing a layer for controlling a threshold voltage of metal-oxide-semiconductor field effect transistor (MOSFETs). The method comprises providing a substrate within a reactor chamber. The substrate comprises a surface. In turn, the surface comprises a silicon oxide surface and/or a high k dielectric surface. Using a cyclical deposition process, a threshold voltage shifting layer is deposited onto the silicon oxide surface and/or on the high k dielectric surface. The threshold voltage shifting layer comprises zinc and oxygen. The cyclical deposition process comprises providing a zinc precursor to the reaction chamber and providing an oxygen reactant to the reaction chamber.

In some embodiments, the oxygen reactant is selected from the list consisting of O₂, O₃, and H₂O.

In some embodiments, the zinc precursor is selected from the list: zinc beta diketonates, zinc alkoxides, zinc alkyls, zinc alkylamides, zinc halides, and zinc hydrides.

In some embodiments, the cyclic deposition process comprises a sequence of a water pulse, a zinc precursor pulse, and an ozone pulse. In some embodiments, the cyclic deposition process comprises a sequence of a water pulse, a zinc precursor pulse, and an oxygen pulse. In some embodiments, the cyclic deposition process comprises a sequence of an ozone pulse, a zinc precursor pulse, and a water pulse. In some embodiments, the cyclic deposition process comprises a sequence of an oxygen pulse, a zinc precursor pulse, and a water pulse. In some embodiments, the cyclic deposition process comprises a sequence of an ozone pulse, a zinc precursor pulse, and an oxygen pulse. In some embodiments, the cyclic deposition process comprises a sequence of an oxygen pulse, a zinc precursor pulse, and an ozone pulse.

In some embodiments, the threshold voltage shifting layer comprises tin, zinc, and oxygen. In other words, the threshold voltage shifting layer comprises tin zinc oxide in these embodiments. Also, in these embodiments, the cyclical deposition process comprises providing an zinc precursor to the reaction chamber, providing a tin precursor to the reaction chamber, and providing an oxygen reactant to the reaction chamber. Advantageously, such layers may be deposited in a cyclical deposition process comprising an alternating sequence of precursor pulses and reagent pulses. In such embodiments, the precursor pulses comprise the provision of a tin precursor and a zinc precursor to the reaction chamber. In such embodiments, the reagent pulses comprise the provision of a reagent to the reaction chamber. Optionally, the precursor pulses and the reagent pulses are separated by purges.

In some embodiments, the threshold voltage shifting layer comprises indium, tin, zinc, and oxygen. In other words, the threshold voltage shifting layer comprises indium tin zinc oxide in these embodiments. Also, in these embodiments, the cyclical deposition process comprises providing an indium precursor, providing a zinc precursor to the reaction chamber, providing a tin precursor to the reaction chamber, and providing an oxygen reactant to the reaction chamber. Advantageously, such layers may be deposited in a cyclical deposition process comprising an alternating sequence of precursor pulses and reagent pulses. The precursor pulses then comprise the provision of an indium precursor, a tin precursor, and a zinc precursor to the reaction chamber. The reagent pulses then comprise the provision of a reagent to the reaction chamber. Optionally, the precursor pulses and the reagent pulses are separated by purges.

In some embodiments, one or more steps of providing a precursor to the reaction chamber are preceded by a surface modification step in which the substrate is contacted with a surface modification agent. The surface modification may activate or deactivate surface states on the substrate, thus influencing the amount of precursor that chemisorbs on the substrate in a subsequent step of providing the precursor. The surface modification step may be carried out at any suitable moment, i.e. before any precursor pulse. For example, a surface modification step may be carried out prior to at least one gallium precursor pulse. For example, a surface modification step may be carried out prior to at least one indium precursor pulse. For example, a surface modification step may be carried out prior to at least one zinc precursor pulse. For example, a surface modification step may be carried out prior to at least one tin precursor pulse. This can advantageously reduce the amount of material which is deposited on the substrate in any given pulse. Thus, the growth rate of the present layers can be reduced, which can result in improved thickness control and/or reduced compositional variations in the growth direction. In addition, executing a surface modification step prior to some pulses, but not prior to other pulses, may be advantageously used for the purpose of composition control.

Thus, in some embodiments, a process as described herein employs a surface modification step in which the substrate is contacted with a surface modification agent before the substrate is contacted with the indium precursor, before the substrate is contacted with the gallium precursor, before the substrate is contacted with the zinc precursor and/or before the substrate is contacted with the tin precursor. Thus, active surface states on the substrate are deactivated to form deactivated surface states. It shall be understood that active surface states readily react with the indium precursor, the gallium precursor, the zinc precursor, and/or one or the tin precursor. Conversely, it shall be understood that the deactivated surface states do not substantially react, or at least react to a lesser degree, with the indium precursor, the gallium precursor, the zinc precursor, and/or the tin precursor.

In some embodiments, the surface modification step is carried out prior to contacting the substrate with each precursor. In other words, in some embodiments, the substrate is contacted with a surface modification agent before the substrate is contacted with an indium precursor, and the substrate is contacted with a surface modification agent before the substrate is contacted with a gallium precursor, the substrate is contacted with a surface modification agent before the substrate is contacted with a zinc precursor, and the substrate is contacted with a surface modification agent before the substrate is contacted with a tin precursor.

In some embodiments, the surface modification agent may be reacted with OH groups on the substrate surface. Exemplary surface modification agents include alcohols and acid anhydrides. Suitable alcohols include methanol, ethanol, and/or isopropanol. Suitable acid anhydrides include formic anhydride and acetic anhydride.

In an exemplary embodiment, a method as described herein comprises forming a layer by cyclically executing the following first sub-cycle: a substrate having a surface terminated with reactive surface terminations, e.g. having an OH-terminated surface, is exposed to a surface modification agent which de-activates a part of the reactive surface terminations. Optionally, the reaction chamber containing the substrate is subsequently purged. Then, the surface is exposed to a first precursor (e.g. a zinc precursor, a gallium precursor, a zinc precursor, or an indium precursor). The first precursor only substantially reacts with active, i.e. non-deactivated, reactive surface terminations. Optionally, the reaction chamber containing the substrate is then purged. Then, the substrate is exposed to an oxygen reactant such as H₂O or O₃, which results in the regeneration of the reactive surface terminations. Optionally, the reaction chamber containing the substrate is subsequently purged. Thus a layer comprising an oxide of a first element, e.g. zinc oxide, gallium oxide, zinc oxide, or indium oxide is formed, and its growth rate can be suitably controlled (i.e. reduced) by means of the surface modification agent. The first sub-cycle may be repeated any number of times in order to arrive at a desired layer thickness.

In another exemplary embodiment, the cyclic deposition process further comprises a second sub-cycle comprising exposing the substrate to the surface modification agent once more, which again de-activates a part of the reactive surface terminations. Then, the surface is exposed to a second precursor (e.g. a zinc precursor, a gallium precursor, a tin precursor, or an indium precursor) which only substantially reacts with the active reactive surface terminations. Optionally, the reaction chamber containing the substrate is then purged. Then, the substrate is exposed to a co-reactant such as H₂O or O₃, which results in the regeneration of the reactive surface terminations. Optionally, the reaction chamber containing the substrate is subsequently purged. Thus a layer comprising a mixture of a first oxide and a second oxide is formed, and its growth rate can be suitably controlled (i.e. reduced) by means of the surface modification agent. When the use of the surface modification agent is omitted from one of the first or the second sub-cycle, the composition of the layer can be effectively controlled. The first sub-cycle and the second sub-cycle may be repeated any number of times in order to arrive at a desired layer thickness. When the use of the surface modification agent is omitted from the first or second sub-cycle, the composition of the layer can be effectively controlled.

In another exemplary embodiment, the cyclical deposition process further comprises a third sub-cycle which also comprises exposing the substrate to the surface modification agent which then de-activates a part of the reactive surface terminations. Then, the surface is exposed to a third precursor (e.g. a zinc precursor, a gallium precursor, a tin precursor, or an indium precursor) which only reacts with the active reactive surface terminations. Optionally, the reaction chamber containing the substrate is then purged. Then, the substrate is exposed to a co-reactant such as H₂O or O₃, which results in the regeneration of the reactive surface terminations. Optionally, the reaction chamber containing the substrate is subsequently purged. Thus a layer comprising a mixture of a first oxide, a second oxide, and a third oxide is formed, and its growth rate can be suitably controlled (i.e. reduced) by means of the surface modification agent. When the use of the surface modification agent is omitted from one or two sub-cycles chosen from the first, the second, and the third sub-cycle, the composition of the layer can be effectively controlled.

In another exemplary embodiment, the cyclical deposition process further comprises a fourth sub-cycle which also comprises exposing the substrate to the surface modification agent which then de-activates a part of the reactive surface terminations. Then, the surface is exposed to a fourth precursor (e.g. a zinc precursor, a gallium precursor, a tin precursor, or an indium precursor) which only substantially reacts with the active reactive surface terminations. Optionally, the reaction chamber containing the substrate is then purged. Then, the substrate is exposed to a co-reactant such as H₂O or O₃, which results in the regeneration of the reactive surface terminations. Optionally, the reaction chamber containing the substrate is subsequently purged. Thus a layer comprising a mixture of a first oxide, a second oxide, a third oxide, and a fourth oxide is formed, and its growth rate can be suitably controlled (i.e. reduced) by means of the surface modification agent. When the use of the surface modification agent is omitted from one, two, or three sub-cycles chosen from the first, the second, the third, and the fourth sub-cycle, the composition of the layer can be effectively controlled.

In some embodiments, the substrate is exposed to two or more precursors simultaneously after the substrate has been exposed to the surface modification agent.

In some embodiments, the first sub-cycle, the second sub-cycle, the third sub-cycle, and/or the fourth sub-cycle are repeated one or more times before the next sub-cycle occurs. In some embodiments, the threshold voltage shifting layer has a thickness from at least 0.03 nm to at most 1.0 nm, or a thickness of at least 0.05 nm to at most 0.5 nm, or a thickness of at least 0.1 nm to at most 0.2 nm, or a thickness of at least 0.5 nm to at most 1.0 nm, or a thickness of at least 0.2 nm to at most 0.5 nm, or a thickness of at least 0.1 nm to at most 0.2 nm, or a thickness of at least 0.05 nm to at most 0.1 nm, or a thickness of at least 0.03 to at most 0.05 nm. In some embodiments the threshold voltage shifting layer has a thickness less than 3.0 nm. In some embodiments the threshold voltage shifting layer has a thickness less than 2.0 nm. In some embodiments the threshold voltage shifting layer has a thickness less than 1.0 nm. In some embodiments the threshold voltage shifting layer has a thickness less than 0.5 nm. In some embodiments the threshold voltage shifting layer has a thickness less than 0.4 nm. In some embodiments the threshold voltage shifting layer has a thickness less than 0.3 nm. In some embodiments the threshold voltage shifting layer has a thickness less than 0.2 nm. In some embodiments the threshold voltage shifting layer has a thickness less than 0.1 nm. In some embodiments, the threshold voltage shifting layer has a thickness less than 0.05 nm.

In some embodiments, the threshold voltage shifting layer is deposited at a temperature of at least 30° C. to at most 450° C., or of at least 50° C. to at most 400° C., or of at least 80° C. to at most 300° C., or of at least 80° C. to at most 150° C., or of at least 150° C. to at most 200° C., or of at least 200° C. to at most 250° C., or of at least 250° C. to at most 300° C.

In some embodiments, the threshold voltage shifting layer is deposited at a pressure of at least 0.1 Torr to at most 20.0 Torr, or of at least 1.0 Torr or at most 10.0 Torr, or at a pressure of at least 2.0 Torr to at most 6.0 Torr, or at a pressure of at least 3.0 Torr to at most 5.0 Torr.

In some embodiments, the MOSFET comprises a gate all around structure.

In some embodiments, the gate all around structure includes a semiconductor material covered with a silicon oxide layer. The threshold voltage shifting layer is deposited on the silicon oxide layer. The threshold voltage shifting layer may be suitably covered by a high-k dielectric layer.

In some embodiments, the gate all around structure includes a semiconductor material covered with a silicon oxide layer. The silicon oxide layer is covered with a high-k dielectric layer. The threshold voltage shifting layer is deposited on the high-k dielectric layer.

In some embodiments, the cyclical deposition process comprises a cyclical chemical vapor deposition process.

In some embodiments, the cyclical deposition process comprises a thermal process.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process.

Further described is a structure comprising a threshold voltage shifting layer formed according to a method according to the present disclosure.

In some embodiments, the structure comprises a high-k dielectric layer between the threshold voltage shifting layer and a substrate. In some embodiments the structure comprises the following sequence of layers, in the following order: silicon oxide/threshold shifting layer/hafnium oxide/titanium nitride. As an alternative to hafnium oxide, another high-k dielectric such as aluminum oxide or niobium oxide may be used as well. In this configuration, the threshold shifting layer may have a thickness of, for example, from 0.03 nm to 1.0 nm, e.g. a thickness of 0.05 nm to 0.5 nm, e.g. a thickness of about 0.1 nm to 0.2 nm. Such configurations are particularly useful for inducing a positive threshold voltage shift in p-MOSFETS. Also, such configurations are particularly useful for inducing a negative threshold voltage shift in n-MOSFETS.

In some embodiments, the structure comprises a threshold voltage shifting layer between a high k dielectric layer and a substrate. In some embodiments the structure comprises the following sequence of layers, in the following order: silicon oxide, hafnium oxide, threshold shifting layer, titanium nitride. The silicon oxide layer may be an interfacial silicon oxide layer formed on a silicon substrate, e.g. as a chemical oxide. As an alternative to hafnium oxide, another high-k dielectric such as aluminum oxide or niobium oxide may be used as well. In this configuration, the threshold shifting layer may have a thickness of, for example, from 0.03 nm to 1.0 nm, e.g. a thickness of 0.05 nm to 0.5 nm, e.g. a thickness of 0.1 nm to 0.2 nm. Such configurations are particularly useful for inducing a positive threshold voltage shift in p-MOSFETS. Also, such configurations are particularly useful for inducing a negative threshold voltage shift in n-MOSFETS.

In some embodiments, the gallium oxide layer has a thickness of less than 0.3 nm.

Further described is a p-channel gate all around metal oxide semiconductor field effect transistor comprising a structure according to the present disclosure.

Further described is an n-channel gate all around metal oxide semiconductor field effect transistor comprising a structure according to the present disclosure.

Further described is a system comprising one or more reaction chambers; a precursor gas source comprising a gallium precursor; an oxygen reactant gas source comprising an oxygen reactant; an exhaust source; and a controller. The controller is configured to control gas flow into at least one of the one or more reaction chambers to form a layer for controlling a threshold voltage of a MOSFET such as an n-channel MOSFET or a p-channel MOSFET according to a method as described herein. The n-channel MOSFET or p-channel MOSFET may, for example, be comprised in a CMOS-based integrated circuit.

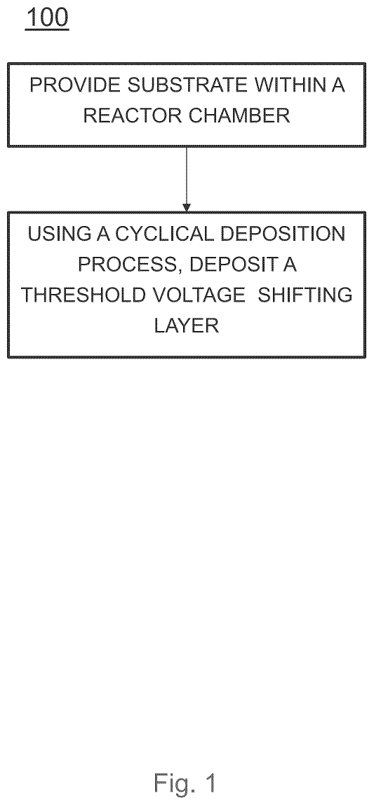

Turning now to the figures, FIG. 1 illustrates a method 100 in accordance with exemplary embodiments of the disclosure. Method 100 can be used to, for example, form a gate electrode structure suitable for PMOS, NMOS, and/or CMOS devices, such as for uses as a threshold voltage shifting layer in a CMOS device. The present layers are particularly suitable for use as threshold voltage control layers in n-or p-channel MOSFETs. However, unless otherwise noted, the methods are not limited to such applications.

Method 100 includes the steps of providing a substrate within a reaction chamber of a reactor (step 102) and using a cyclical deposition process, depositing a layer comprising one or more of gallium oxide, tin oxide, indium gallium oxide, zinc oxide, onto a surface of the substrate (step 104).

During step 102, a substrate is provided within a reaction chamber. The reaction chamber used during step 102 can be or include a reaction chamber of a chemical vapor deposition reactor system configured to perform a cyclical deposition process. Additionally or alternatively, the reaction chamber used during step 102 can be or can include a reaction chamber of an atomic layer deposition reactor system configured to perform a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of at least 50° C. to at most 400° C., or of at least 80° C. to at most 300° C., or of at least 80° C. to at most 150° C., or of at least 150° C. to at most 200° C., or of at least 200° C. to at most 250° C., or of at least 250° C. to at most 300° C.

In addition to controlling the temperature of the substrate, a pressure within the reaction chamber may also be regulated. For example, in some embodiments of the disclosure, the pressure within the reaction chamber during step 102 may be at least 1.0 Torr to at most 10.0 Torr, or at least 2.0 Torr to at most 6.0 Torr, or at least 3.0 Torr to at most 5.0 Torr.

During step 104, a layer comprising gallium oxide, tin oxide, indium gallium oxide, and/or zinc oxide is deposited onto a surface of the substrate using a cyclical deposition process. The cyclical deposition process can include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of precursors and reactants. Such a process may be referred to as cyclical CVD. In some embodiments, a cyclical CVD process may comprise the introduction of two or precursors and reactants into the reaction chamber, wherein there may be a time period of overlap between the two or more precursors and reactants in the reaction chamber resulting in both an ALD component of the deposition and a CVD component of the deposition. This is referred to as a hybrid process. In accordance with further examples, a cyclical deposition process may comprise the continuous flow of one oxygen reactant/precursor and the periodic pulsing of precursor or reactant into the reaction chamber. Preferably though, the present methods are carried out in an ALD mode, i.e. in a mode in which precursor pulses and oxygen reactants are separated from each other by purges. Doing so allows to minimize gas phase reactions. Note though that different precursor pulses do not necessarily have to be separated from each other by means of purges when the precursors in question are not prone to reacting with each other in the gas phase.

In accordance with some examples of the disclosure, the cyclical deposition process is a thermal deposition process. In these cases, the cyclical deposition process does not include use of a plasma to form activated species for use in the cyclical deposition process.

The cyclical deposition process can include (e.g., separately and/or sequentially) providing a gallium, indium, tin and/or zinc precursor to the reaction chamber and providing an oxygen reactant to the reaction chamber. The gallium, indium, tin and/or zinc precursor can include one or more of the precursors mentioned elsewhere herein.

In the case of thermal cyclical deposition processes, a duration of the step of providing an oxygen reactant to the reaction chamber can be relatively long to allow the oxygen reactant to react with the precursor or a derivative thereof. For example, the duration can be greater than or equal to 5 seconds or greater than or equal to 10 seconds or from at least 1.0 seconds to at most 50.0 seconds, or from at least 2.0 seconds to at most 20.0 seconds, or from at least 5.0 seconds to at most 15.0 seconds.

As part of step 104, the reaction chamber can be purged using a vacuum and/or an inert gas to mitigate gas phase reactions between precursors and oxygen reactants and enable partly or fully self-saturating surface reactions—e.g., in the case of ALD. Additionally or alternatively, the substrate may be moved to separately contact a first vapor phase oxygen reactant, e.g. a precursor, and a second vapor phase oxygen reactant, e.g. an oxygen-containing gas. Surplus chemicals and reaction byproducts, if any, can be removed from the substrate surface or reaction chamber, such as by purging the reaction space or by moving the substrate, before the substrate is contacted with the next reactive chemical. The reaction chamber can be purged after the step of providing a precursor to the reaction chamber and/or after the step of providing an oxygen reactant to the reaction chamber.

In some embodiments of the disclosure, method 100 includes repeating a unit deposition cycle that includes (1) providing one or more of an indium precursor, gallium precursor, tin precursor, and zinc precursor to the reaction chamber and (2) providing an oxygen reactant to the reaction chamber, with optional purge or move steps after step (1) and/or step (2). The deposition cycle can be repeated one or more times, based on, for example, a desired thickness of the threshold voltage shifting layer. For example, if the thickness of the threshold voltage shifting layer is less than desired for a particular application, then the step of providing a precursor to the reaction chamber and providing an oxygen reactant to the reaction chamber can be repeated one or more times. Once the threshold voltage shifting layer has been deposited to a desired thickness, the substrate can be subjected to additional processes to form a device structure and/or device.

In some embodiments, a step coverage of the layer containing gallium oxide, indium oxide, tin oxide and/or zinc oxide, i.e. the threshold voltage shifting layer, is equal to or greater than about 50%, or greater than about 80%, or greater than about 90%, or about 95%, or about 98%, or about 99% or greater, in/on structures having aspect ratios (height/width) of more than about 2, more than about 5, more than about 10, more than about 25, more than about 50, more than about 100, or between about 10 and 100 or about 5 to about 25.

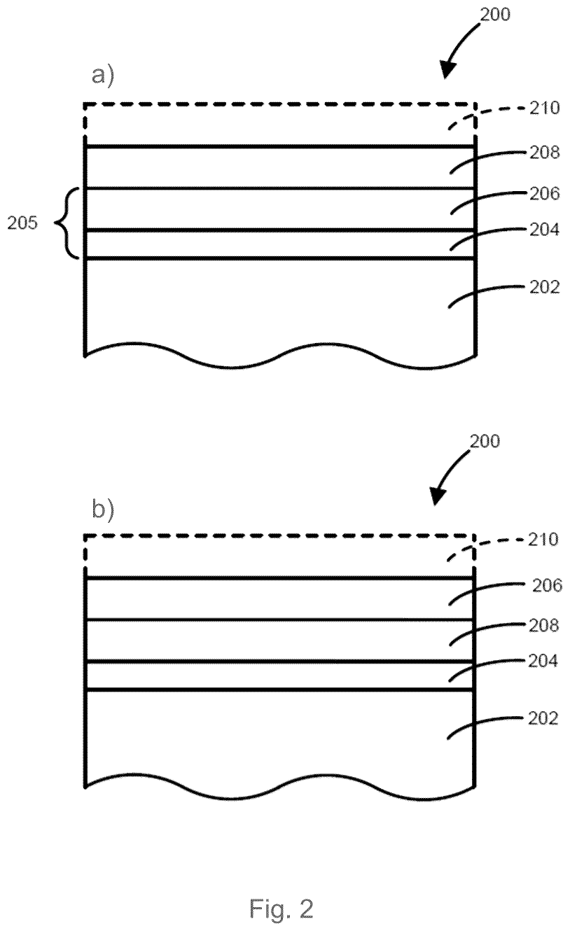

FIG. 2, panel a) illustrates a structure/a portion of a device 200 in accordance with additional examples of the disclosure. Device or structure 200 includes a substrate 202, dielectric or insulating material 205, and a layer containing gallium oxide, indium oxide, tin oxide and/or zinc oxide 208. In the illustrated example, structure 200 also includes an additional conducting layer 210.

Substrate 202 can be or include any of the substrate material described herein. Dielectric or insulating material 205 can include one or more dielectric or insulating material layers. By way of example, dielectric or insulating material 205 can include an interface layer 204 and a high-k material 206 deposited overlying interface layer 204. In some cases, interface layer 204 may not exist or may not exist to an appreciable extent. Interface layer 204 can include an oxide, such as a silicon oxide, which can for example be formed on a, for example monocrystalline silicon, surface of the substrate 202 using, for example, a chemical oxidation process or an oxide deposition process. High-k material 206 can be or include, for example, a metal oxide having a dielectric constant greater than about 7. In some embodiments, the high-k material has a dielectric constant higher than the dielectric constant of silicon oxide. Exemplary high-k materials include hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃) or lanthanum oxide (La₂O₃), mixtures thereof, and laminates thereof.

FIG. 2, panel b) illustrates another structure/a portion of a device 200 in accordance with additional examples of the disclosure. It is similar to the structure shown in FIG. 2, panel a), except that the threshold voltage shifting layer 208 is situated between the interface layer 204 and the high-k material 206.

The threshold voltage shifting layer 208 can be formed according to a method as described herein. Because the threshold voltage shifting layer 208 is formed using a cyclical deposition process, a concentration of gallium oxide, indium oxide, tin oxide and/or zinc oxide and/or other constituents in the threshold voltage shifting layer 208 can vary from a bottom of the threshold voltage shifting layer 208 to a top of threshold voltage shifting layer 208 by, for example, controlling an amount of gallium, indium, tin, and/or zinc precursor and/or oxygen reactant and/or respective pulse times during one or more deposition cycles. In some cases, the threshold voltage shifting layer 208 can have a stoichiometric composition. An effective work function and other properties of a gate stack comprising the threshold voltage shifting layer 208 can be altered by altering an amount of gallium indium, tin, zinc and/or other compounds in the layer or in a deposition cycle.

The threshold voltage shifting layer 208 can include impurities, such as halides, hydrogen, carbon or the like, for example in an amount of less than 10.0 atomic percent, less than 6.0 atomic percent, less than 4.0 atomic percent, less than 2.0 atomic percent, less than 1.0 atomic percent, less than 0.2 atomic percent, or less than 0.1 atomic percent, or less than 0.05 atomic percent, alone or combined.

When used to replace layers that may include aluminum, rather than gallium, indium, zinc and/or tin, the threshold voltage shifting layer 208 may be relatively thin, e.g. can be less than 0.5 nm thick, or less than 0.4 nm thick, or can be less than 0.3 nm thick, or can be less than 0.2 nm thick, or can be less than 0.1 nm thick, which may be desirable for many applications, including work function and/or threshold voltage adjustment layers, e.g. in the gate stack of n-or p-channel MOSFETs.

An effective work function of a gate stack comprising a threshold voltage shifting layer 208 can be >4.6 eV, >4.7 eV, >4.8 eV, >4.9 eV, >4.95 eV, or >5.0 eV. An effective work function of a gate stack can be shifted by about 30 meV to about 400 meV, or about 30 meV to about 200 meV, or about 50 meV to about 100 meV using a layer containing gallium oxide, indium oxide, tin oxide and/or zinc oxide as described herein.

A threshold voltage shifting layer 208 can form a continuous film—e.g., using method 100—at a thickness of less than <5 nm, <4 nm, <3 nm, <2 nm, <1.5 nm, <1.2 nm, <1.0 nm, or <0.9 nm. The layer containing gallium oxide, indium oxide, tin oxide and/or zinc oxide 208 can be relatively smooth, with relatively low grain boundary formation. In some cases, the layer containing gallium oxide, indium oxide, tin oxide and/or zinc oxide 208 may be amorphous, with relatively low columnar crystal structures (as compared to e.g. TiN). RMS roughness of an exemplary layer containing gallium oxide, indium oxide, tin oxide and/or zinc oxide 208 can be <1.0 nm, <0.7 nm, <0.5 nm, <0.4 nm, <0.35 nm, or <0.3 nm, or <0.25 nm, or <0.20 nm, or <0.15 nm, or <0.1 nm, at a thickness of less than 10 nm.

Alternatively, the threshold voltage shifting layer 208 may be thinner than e.g. 1.0 nm, 0.5 nm, 0.3 nm, 0.2 nm, or 0.1 nm and be discontinuous. For example, the layer may comprise isolated islands, gaps, and/or holes. The threshold voltage shifting layer 208 may even entirely consist of a plurality of isolated atoms and/or clusters of atoms.

Additional conducting layer 212 can include, for example, metal, such as a refractory metal or the like.

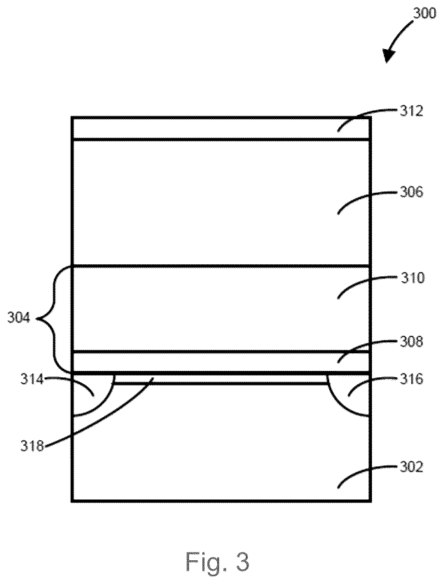

FIG. 3 illustrates another exemplary structure 300 in accordance with examples of the disclosure. Device or structure 300 includes a substrate 302, dielectric or insulating material 304, and a threshold voltage shifting layer 306. The dielectric or insulating material comprises an interfacial layer 308 and a high-k dielectric layer 310. A suitable interfacial layer includes silicon oxide. In the illustrated example, structure 300 also includes an additional conducting layer 312. In the illustrated example, the threshold voltage shifting layer 306 is deposited on top of the high-k dielectric layer 310. Alternatively, the threshold voltage shifting layer 306 may be deposited on top of the interfacial layer 308, and the high-k dielectric layer 310 may be deposited on the threshold voltage shifting layer 306.

In the illustrated example, the substrate 302 includes a source region 314, a drain region 316, and a channel region 318. Although illustrated as a horizontal structure, structures and devices in accordance with examples of the disclosure can include vertical and/or three-dimensional structures and devices, such as FinFET devices, gate-all-around field effect transistors, and stacked device architectures.

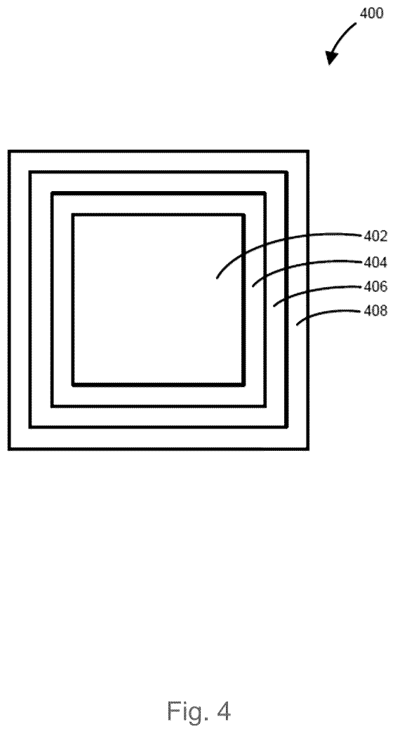

FIG. 4 illustrates another structure 400 in accordance with examples of the disclosure. Structure 400 is suitable for gate all around field effect transistors (GAA FET) (also referred to as lateral nanowire FET) devices and the like.

In the illustrated example, structure 400 includes a semiconductor material 402, a dielectric material 404, a threshold shifting layer 406, and a conducting layer 408. The dielectric material suitably comprises an interfacial layer, e.g. silicon oxide, and a high-k dielectric layer, analogous to the layer sequences illustrated in FIGS. 2 and 3. Structure 400 can be formed overlying a substrate, including any substrate materials described herein.

In the illustrated example, the threshold voltage shifting layer 406 is deposited on top of the dielectric layer. Alternatively (embodiment not shown in FIG. 4), the threshold voltage shifting layer 406 may be deposited on top of an interfacial layer, and a high-k dielectric layer may be deposited on the threshold voltage shifting layer 406.

Semiconductor material 402 can include any suitable semiconducting material. For example, semiconductor material 402 can include Group IV, Group III-V, or Group II-VI semiconductor material. By way of example, semiconductor material 402 includes silicon, or more specifically monocrystalline silicon.

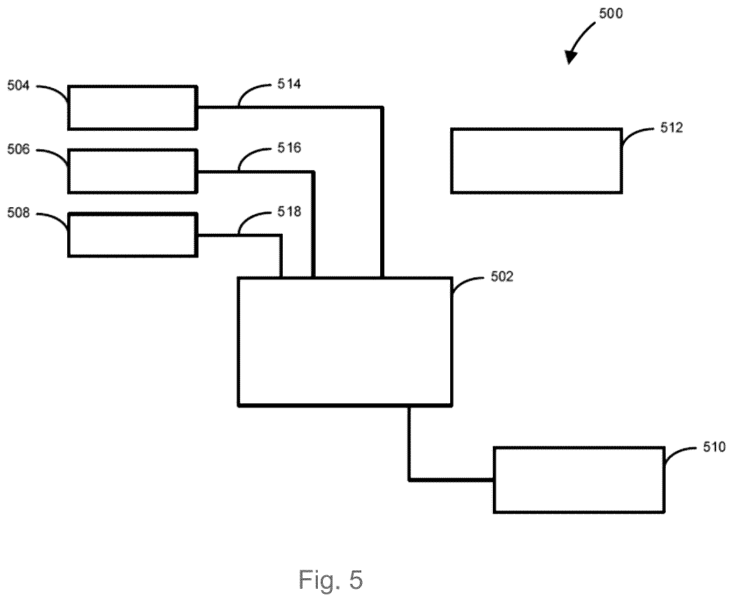

FIG. 5 illustrates a system 500 in accordance with yet additional exemplary embodiments of the disclosure. System 500 can be used to perform a method as described herein and/or form a structure or device portion as described herein.

In the illustrated example, system 500 includes one or more reaction chambers 502, a precursor gas source 504, an oxygen reactant gas source 506, a purge gas source 508, an exhaust source 510, and a controller 512.

Reaction chamber 502 can include any suitable reaction chamber, such as an ALD or CVD reaction chamber.

Precursor gas source 504 can include a vessel and one or more precursors as described herein-alone or mixed with one or more carrier (e.g., inert) gases. Oxygen reactant gas source 506 can include a vessel and one or more oxygen reactants as described herein-alone or mixed with one or more carrier gases. Purge gas source 508 can include one or more inert gases as described herein. Although illustrated with three gas sources 504-508, system 500 can include any suitable number of gas sources. Gas sources 504-508 can be coupled to reaction chamber 502 via lines 514-518, which can each include flow controllers, valves, heaters, and the like.

Exhaust source 510 can include one or more vacuum pumps.

Controller 512 includes electronic circuitry and software to selectively operate valves, manifolds, heaters, pumps and other components included in the system 500. Such circuitry and components operate to introduce precursors, oxygen reactants, and purge gases from the respective sources 504-508. Controller 512 can control timing of gas pulse sequences, temperature of the substrate and/or reaction chamber, pressure within the reaction chamber, and various other operations to provide proper operation of the system 500. Controller 512 can include control software to electrically or pneumatically control valves to control flow of precursors, oxygen reactants and purge gases into and out of the reaction chamber 502. Controller 512 can include modules such as a software or hardware component, e.g., a FPGA or ASIC, which performs certain tasks. A module can advantageously be configured to reside on the addressable storage medium of the control system and be configured to execute one or more processes.

Other configurations of system 500 are possible, including different numbers and kinds of precursor and oxygen reactant sources and purge gas sources. Further, it will be appreciated that there are many arrangements of valves, conduits, precursor sources, and purge gas sources that may be used to accomplish the goal of selectively feeding gases into reaction chamber 502. Further, as a schematic representation of a system, many components have been omitted for simplicity of illustration, and such components may include, for example, various valves, manifolds, purifiers, heaters, containers, vents, and/or bypasses.

During operation of reactor system 500, substrates, such as semiconductor wafers (not illustrated), are transferred from, e.g., a substrate handling system to reaction chamber 502. Once substrate(s) are transferred to reaction chamber 502, one or more gases from gas sources 504-508, such as precursors, oxygen reactants, carrier gases, and/or purge gases, are introduced into reaction chamber 502.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a structure, the method comprising:
providing a substrate within a reaction chamber, the substrate comprising a silicon oxide layer and a high-k dielectric layer overlying the silicon oxide layer; and
depositing a threshold voltage shifting layer consisting essentially of gallium oxide directly onto the high-k dielectric layer, wherein depositing the threshold voltage shifting layer comprises:
providing a gallium precursor to the reaction chamber, and
providing an oxygen reactant to the reaction chamber.

2. The method of claim 1, wherein the oxygen reactant comprises one or more of O₂, O₃, H₂O, H₂O₂, and N₂O.

3. The method of claim 1, wherein the gallium precursor comprises one or more of gallium beta diketonates, gallium alkoxides, gallium alkyls, gallium alkylamides, gallium halides, and gallanes.

4. The method of claim 1, wherein the gallium precursor comprises one or more of gallium tris(dimethylamide), gallium(III) acetylacetonate, dimethylgallium isopropoxide, gallium chloride, and trimethylgallium.

5. The method of claim 1, wherein the threshold voltage shifting layer has a thickness from at least 0.03 nm to at most 1.0 nm.

6. The method of claim 1, wherein the threshold voltage shifting layer is deposited at a temperature of at least 80° C. to at most 300° C.

7. The method of claim 1, wherein the threshold voltage shifting layer is deposited at a pressure of at least 1.0 Torr to at most 10.0 Torr.

8. The method of claim 1, wherein depositing a threshold voltage shifting layer comprises a cyclical deposition process.

9. The method of claim 8, wherein the cyclical deposition process comprises a cyclical chemical vapor deposition (cyclical CVD) process.

10. The method of claim 8, wherein the cyclical deposition process is a thermal process.

11. The method of claim 1, wherein the high-k dielectric layer comprises hafnium oxide.

12. The method of claim 1, further comprising forming a conducting layer directly onto the threshold voltage shifting layer.

13. The method of claim 12, wherein the conducting layer comprises titanium nitride.

14. A method for forming a structure, the method comprising:
providing a substrate within a reaction chamber, the substrate comprising a silicon oxide layer;
depositing a threshold voltage shifting layer comprising gallium oxide directly onto the silicon oxide layer, wherein depositing the threshold voltage shifting layer comprising gallium oxide comprises:
providing a gallium precursor to the reaction chamber, and
providing an oxygen reactant to the reaction chamber; and
forming a high-k dielectric layer directly on the threshold voltage shifting layer.

15. The method of claim 14, wherein the gallium precursor comprises one or more of gallium beta diketonates, gallium alkoxides, gallium alkyls, gallium alkylamides, gallium halides, and gallanes.

16. The method of claim 14, wherein the gallium precursor comprises one or more of gallium tris(dimethylamide), gallium(III) acetylacetonate, dimethylgallium isopropoxide, gallium chloride, and trimethylgallium.

17. The method of claim 14, wherein the threshold voltage shifting layer has a thickness from at least 0.03 nm to at most 1.0 nm.

18. The method of claim 14, wherein the threshold voltage shifting layer is deposited at a temperature of at least 80° C. to at most 300° C.

19. The method of claim 14, further comprising forming a conducting layer comprising titanium nitride directly onto the high-k dielectric layer.

20. A method for forming a structure, the method comprising:
providing a substrate within a reaction chamber, the substrate comprising a silicon oxide layer;
depositing a threshold voltage shifting layer comprising gallium oxide on the silicon oxide layer, wherein the threshold voltage shifting layer has a thickness from at least 0.03 nm to at most 1.0 nm; and
forming a high-k dielectric layer.
